(19) United States
(12) Patent Application Publication
(10) Pub. No.: US 2017/0062062 A1
(43) Pub. Date: Mar. 2, 2017

(54) SEMICONDUCTOR MEMORY DEVICE

(71) Applicant: KABUSHIKI KAISHA TOSHIBA, Minato-ku (JP)

(72) Inventor: Kenji TANABE, Kamakura (JP)

(73) Assignee: KABUSHIKI KAISHA TOSHIBA, Minato-ku (JP)

(21) Appl. No.: 15/007,620

(22) Filed: Jan. 27, 2016

Related U.S. Application Data
(60) Provisional application No. 62/210,673, filed on Aug. 27, 2015.

(51) Int. Cl. G11C 16/26; G11C 16/04; G11C 16/24; G11C 16/30

(52) U.S. Cl. CPC G11C 16/26; G11C 16/30; G11C 16/0483; G11C 16/24

(57) ABSTRACT

According to one embodiment, a semiconductor memory device includes first and second select transistors, first and second bit lines, a first switch circuit and a sense amplifier. The first select transistor is electrically connected to the first memory cell. The first bit line is electrically connected to the first select transistor. The second select transistor is electrically connected to the second memory cell. The second bit line is electrically connected to the second select transistor. The first switch circuit is electrically connected between the first bit line and the second bit line. The sense amplifier is electrically connected to the second bit line, and senses data stored in the first and second memory cells.

### CROSS-REFERENCE TO RELATED APPLICATIONS

This application claims the benefit of U.S. Provisional Application No. 62/210,673, filed Aug. 27, 2015, the entire contents of which are incorporated herein by reference.

### FIELD

Embodiments described herein relate generally to a semiconductor memory device.

### BACKGROUND

In a read operation (hereinafter referred to as a power-on read operation) for setting various memory parameters during power-on, voltage sensing in which read accuracy deteriorates but current consumption is low is generally performed instead of current sensing in which read accuracy is high but current consumption is high. The deterioration of read accuracy caused by the voltage sensing is allowable in reading of a memory cell capable of storing 1-bit data (SLC: single-level cell).

However, even the voltage sensing has a problem: the capacity of a global bit line needs to be precharged, which increases current consumption, and time is required for a read time. Another problem is that a leak current of the global bit line is relatively high and is therefore added to a cell current, so that read accuracy deteriorates.

### BRIEF DESCRIPTION OF THE DRAWING

FIG. 1 is a block diagram showing the configuration of a semiconductor memory device according to a first embodiment;

FIG. 2 is a circuit diagram showing the configurations of a memory cell array and sense modules according to the first embodiment;

FIG. 3 is a timing chart showing a power-on read operation in the semiconductor memory device according to the first embodiment;

FIG. 4 is a circuit diagram showing the configurations of a memory cell array and sense modules according to a second embodiment;

FIG. 5 is a timing chart showing a power-on read operation in a semiconductor memory device according to the second embodiment;

FIG. 6 is a circuit diagram showing the configurations of a memory cell array and sense modules according to a third embodiment;

FIG. 7 is a timing chart showing a power-on read operation in a semiconductor memory device according to the third embodiment;

FIG. 8 is a block diagram showing the configuration of a selection circuit according to the first to third embodiments;

FIG. 9 is a circuit diagram showing the configuration of a power-on reset circuit according to the first to third embodiments; and

FIG. 10 is a circuit diagram showing the configuration of an internal power generation circuit according to the first to third embodiments.

### DETAILED DESCRIPTION

Hereinafter, semiconductor memory devices according to the embodiments will described with reference to the drawings. In the following explanation, components having the same functions and configurations are provided with the same reference signs. The embodiments described below illustrate apparatuses and methods that embody the technical concept of the embodiments, and do not specify the materials, shapes, structures, and locations of the components to those described below.

In general, according to one embodiment, a semiconductor memory device includes first and second memory cells, first and second select transistors, first and second bit lines, a first switch circuit, and a sense amplifier. The first select transistor is electrically connected to the first memory cell. The first bit line is electrically connected to the first select transistor. The second select transistor is electrically connected to the second memory cell. The second bit line is electrically connected to the second select transistor. The first switch circuit is electrically connected between the first bit line and the second bit line. The sense amplifier is electrically connected to the second bit line, and senses data stored in the first memory cell and the second memory cell.

### 1. First Embodiment

A semiconductor memory device according to a first embodiment is described.

### 1.1 Overall Configuration of Semiconductor Memory Device

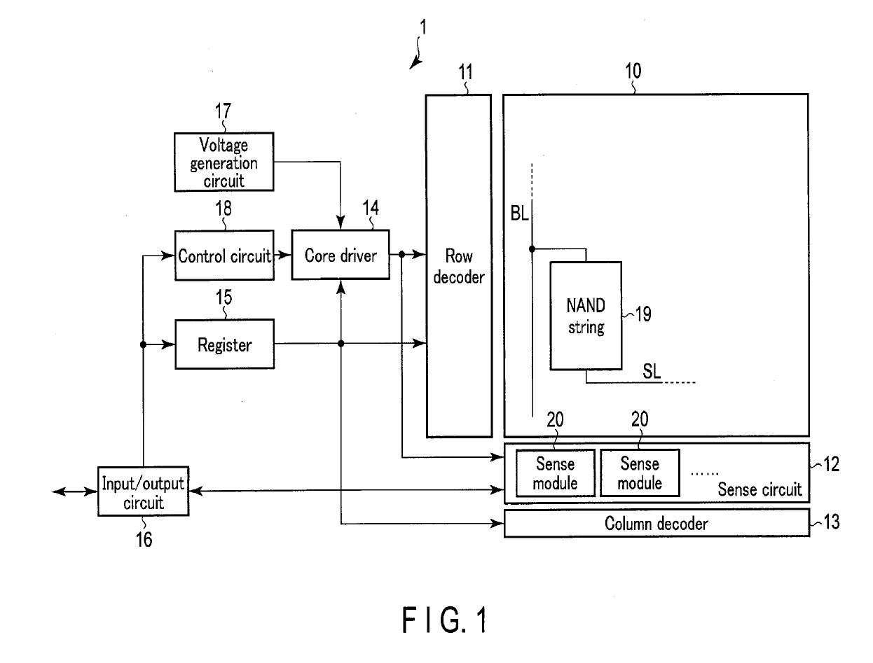

FIG. 1 is a block diagram showing the configuration of the semiconductor memory device according to the first embodiment.

As shown, a semiconductor memory device 1 includes a memory cell array 10, a row decoder 11, a sense circuit 12, a column decoder 13, a core driver 14, a register 15, an input/output circuit 16, a voltage generation circuit 17, and a control circuit 18. Here, a NAND flash memory is described as an example of the semiconductor memory device 1.

The memory cell array 10 includes NAND strings 19 in which nonvolatile memory cells are connected in series. Word lines (not shown) are connected to the gates of the memory cells in the NAND string 19. A bit line BL is connected to the drain of the memory cell at one end of the NAND string 19. A source line SL is connected to the source of the memory cell at the other end.

The row decoder 11 selects the row direction of the memory cell array 10. In other words, in writing, reading, and erasing of data, the row decoder 11 selects one of the word lines, and applies necessary voltages to the selected word line and unselected word lines.

The sense circuit 12 has a sense module 20 provided to correspond to the bit line BL. The sense module 20 senses and amplifies data read in the bit line BL during data reading. The sense module 20 also transfers write data to the bit line BL during data writing.

The column decoder 13 selects the column direction of the memory cell array 10. In other words, in the transfer of write data and read data, the column decoder 13 selects one of the sense modules 20.

The voltage generation circuit 17 generates voltages necessary for data writing, reading, and erasing, for example, in response to an instruction from the control circuit 18, and supplies the voltages to the core driver 14.

The core driver 14 supplies necessary voltages to the row decoder 11 and the sense circuit 12 among the voltages supplied from the voltage generation circuit 17, for example, in response to an instruction from the control circuit 18. The voltages supplied from the core driver 14 are then transferred to the word lines by the row decoder 11, and applied to the bit line BL by the sense circuit 12.

The input/output circuit 16 controls the input and output of signals between the input/output circuit 16 and a controller or a host device which accesses the semiconductor memory device 1. The read data read by the sense circuit 12 is output from the input/output circuit 16. In addition to the write data, various commands and addresses for writing, reading, and erasing, and status reading are input to the input/output circuit 16.

The register 15 holds the commands and addresses received from the controller or the host device. For example, the register 15 transfers a row address to the row decoder 11 and the core driver 14, and transfers a column address to the column decoder 13.

In accordance with the commands received from the controller or the host device, the control circuit 18 controls the operation of the whole semiconductor memory device 1, that is, the memory cell array 10, the row decoder 11, the sense circuit 12, the column decoder 13, the core driver 14, the register 15, the input/output circuit 16, and the voltage generation circuit 17. Various control signals in the following explanation are generated by, for example, the control circuit 18.

1.1.1 Configuration of Memory Cell Array

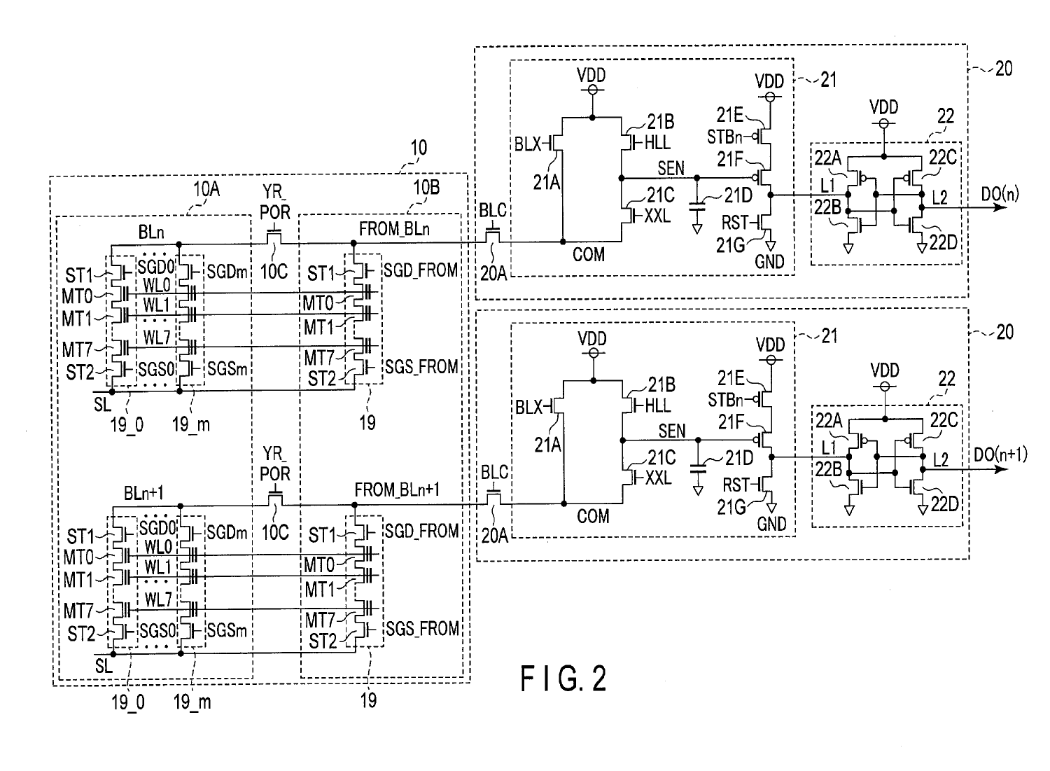

FIG. 2 is a circuit diagram showing the configurations of the memory cell array 10 and the sense modules 20 according to the first embodiment.

The memory cell array 10 includes a data region 10A, a fuse ROM region 10B, and a switch circuit 10C. The switch circuit 10C includes, for example, an n-channel MOS field effect transistor (hereinafter referred to as an nMOS transistor). The data region 10A is used in the write operation and the read operation, and includes memory cells to store data. The fuse ROM region 10B includes memory cells which store various memory parameters to be set during power-on.

The data region 10A has NAND strings 19_0, 19_1, . . . , and 19_m, and a first bit line BLn. Each of the NAND strings 19_0 to 19_m has the same structure. Each of the NAND strings 19_0 to 19_m is hereinafter referred to as the NAND string 19. It is to be noted that m and n indicate natural numbers equal to or more than 0.

The NAND string 19 has memory cells MT0, MT1, . . . , and MT7, a drain side select transistor ST1, and a source side select transistor ST2. The memory cells MT0 to MT7 are connected in series at the sources or drains thereof. The first bit line BLn is connected, via the select transistor ST1, to one end of the serially connected memory cells MT0 to MT7 on the side of the memory cell MT0. The source line SL is connected, via the select transistor ST2, to the other end of the memory cells MT0 to MT7 on the side of the memory cell MT7. Thus, the NAND strings 19_0 to 19_m are connected in parallel between the first bit line BLn and the source line SL.

Each of the memory cells MT0 to MT7 has the same structure. Each of the memory cells MT0 to MT7 is hereinafter referred to as the memory cell MT. The memory cell MT includes a stacked layer structure including a control gate electrode and a floating gate electrode, and is electrically rewritable. The memory cell MT stores binary data or multivalue data depending on the change of the threshold of the transistor determined by a charge amount injected to the floating gate electrode. The memory cell MT may have a metal-oxide-nitride-oxide-silicon (MONOS) structure which traps electrons in a nitride film.

The control gate electrodes of the memory cells MT0 to MT7 of the NAND strings 19_0 to 19_m are connected to the word lines WL0, WL1, . . . , and WL7, respectively. The gates of the select transistors ST1 of the NAND strings 19_0 to 19_m are connected to drain side select gate lines SGD0, SGD1, . . . , and SGDm, respectively. The gates of the select transistors ST2 of the NAND strings 19_0 to 19_m are connected to source side select gate lines SGS0, SGS1, and SGSm, respectively.

The fuse ROM region 10B has one or more NAND strings 19 and a second bit line FROM_BLn. The NAND string 19 in the fuse ROM region 10B has a structure similar to that of the NAND string 19 in the data region 10A. The second bit line FROM_BLn is connected, via the select transistor ST1, to one end of the serially connected memory cells MT0 to MT7 on the side of the memory cell MT0. The source line SL is connected, via the select transistor ST2, to the other end of the memory cells MT0 to MT7 on the side of the memory cell MT7.

The control gate electrodes of the memory cells MT0 to MT7 of the NAND strings 19 in the fuse ROM region 10B are connected to the word lines WL0, WL1, . . . , and WL7, respectively. The gate of the select transistor ST1 of the NAND string 19 is connected to a drain side select gate line SGD_FROM. The gate of the select transistor ST2 of the NAND string 19 is connected to a source side select gate line SGS_FROM. Although one NAND string is shown here, it should be understood that more than one NAND string may be disposed.

The switch circuit 10C is connected between the first bit line BLn and the second bit line FROM_BLn. In accordance with a signal YR_POR input to the gate, the switch circuit 10C connects or disconnects the first bit line BLn and the second bit line FROM_BLn. Specifically, the switch circuit 10C turns off at the start of a power-on read operation, and disconnects the first bit line BLn and the second bit line FROM_BLn. The switch circuit 10C turns on during the read operation or the write operation, and connects the first bit line BLn and the second bit line FROM_BLn.

1.1.2 Configuration of Sense Module

The sense module 20 senses and amplifies the current running through the memory cells in the memory cell array 10 to read data stored in the memory cells. The sense module 20 includes a sense amplifier 21, a sense latch 22, and a clamp nMOS transistor 20A.

The sense amplifier 21 senses and amplifies the current running through the memory cells MT in the memory cell array 10. Specifically, the sense amplifier 21 senses and amplifies the current running through the NAND string 19 connected to the second bit line FROM_BLn during the power-on read operation. The sense amplifier 21 senses and amplifies the current running through the NAND string 19 connected to the first bit line BLn during the read operation.

The sense latch 22 latches data sensed and amplified by the sense amplifier 21. The clamp nMOS transistor 20A restricts the currents running through the first bit line BLn and the second bit line FROM_BLn in accordance with a clamp signal BLC input to the gate.

The configurations of the sense amplifier 21 and the sense latch 22 are described below in detail. The sense amplifier 21 includes nMOS transistors 21A, 21B, 21C, and 21G, p-channel MOS field effect transistors (hereinafter referred to as pMOS transistors) 21E and 21F, and a capacitor 21D.

The source of the nMOS transistor 21A is connected to the drain of the nMOS transistor 20A, and the drain of the nMOS transistor 21A is connected to the drain of the nMOS transistor 21B. A power supply voltage (internal power supply) VDD is supplied to the drains of the nMOS transistors 21A and 21B. The source of the nMOS transistor 21B is connected to the drain of the nMOS transistor 21C, and the source of the nMOS transistor 21C is connected to the drain of the nMOS transistor 20A. A signal BLX is input to the gate of the nMOS transistor 21A. Signals HLL and XXL are input to the gates of the nMOS transistors 21B and 21C, respectively.

The source of the nMOS transistor 21B is connected to a sense node SEN. The sense node SEN is connected to the gate of the pMOS transistor 21F, and also connected to a first electrode of the capacitor 21D. A reference potential such as a ground voltage GND is supplied to a second electrode of the capacitor 21D.

The source of the pMOS transistor 21F is connected to the drain of the pMOS transistor 21E, and a power supply voltage VDD is supplied to the source of the pMOS transistor 21E. The drain of the pMOS transistor 21F is connected to the drain of the nMOS transistor 21G, and a ground voltage GND is supplied to the source of the nMOS transistor 21G. A strobe signal STBn is input to the gate of the pMOS transistor 21E, and a reset signal RST is input to the gate of the nMOS transistor 21G.

The sense latch 22 has first and second inverters having input terminals and output terminals connected to each other. That is, the output terminal (hereinafter also referred to as a latch input terminal) of the first inverter is connected to the input terminal of the second inverter, and the output terminal (hereinafter also referred to as a latch output terminal) of the second inverter is connected to the input terminal of the first inverter.

The first inverter includes a pMOS transistor 22A and an nMOS transistor 22B. The second inverter includes a pMOS transistor 22C and an nMOS transistor 22D. A power supply voltage VDD is supplied to the sources of the pMOS transistors 22A and 22C. Moreover, a ground voltage GND is supplied to the sources of the nMOS transistors 22B and 22D.

The drain of the pMOS transistor 21F in the sense amplifier 21 is connected to the output terminal of the first inverter and the input terminal of the second inverter. The data sensed and amplified by the sense amplifier 21 is latched by the sense latch 22, and output from the sense latch 22 as read data DO(n).

As shown in FIG. 2, the NAND strings 19_0 to 19_m and the NAND string 19 are connected to a first bit line BLn+1 and a second bit line FROM_BLn+1 in the memory cell array 10 as well as to the first bit line BLn and the second bit line FROM_BLn, and a sense module 20 is connected to the second bit line FROM_BLn+1.

### 1.2 Operation of Semiconductor Memory Device

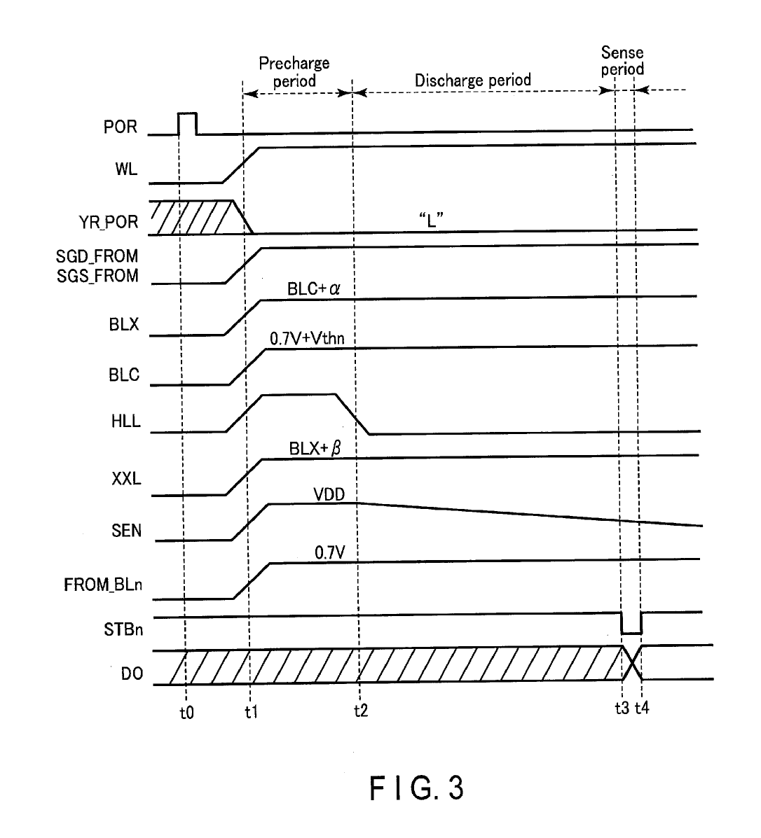

FIG. 3 is a timing chart showing the power-on read operation in the semiconductor memory device according to the first embodiment.

First, at a time to, a power-on reset signal POR is output from a power-on reset circuit in the control circuit 18, and the power-on read operation is then started. The power-on reset circuit will be described later. At the time to, the signal YR_POR is “H” or “L”.

Other signals at the time t0 take the following statuses. The word lines WL, the select signals SGD_FROM and SGS_FROM, the signal BLX, the clamp signal BLC, the signal HLL, and the signal XXL are “L”, and the nMOS transistors to which these signals are input are off. The strobe signal STBn is “H”, and the pMOS transistor 21E to which the strobe signal STBn is input is off. Voltages of the sense node SEN and the bit line FROM_BLn are “L”.

From a time t1 to a time t4, the power-on read operation is then performed. The following operation is performed in a precharge period from the time t1 to the time t2. At the time t1, the signal YR_POR becomes “L”, and the switch circuit 10C turns off. As a result, the first bit line BLn is disconnected from the second bit line FROM_BLn.

Moreover, at the time t1, the word lines WL, the select signals SGD_FROM and SGS_FROM, the signal BLX, the signal BLC, the signal HLL, and the signal XXL become “H”, and the strobe signal STBn remains “H”. As a result, the bit line FROM_BLn is precharged to 0.7 V. Further, the sense node SEN is charged to a power supply voltage VDD. In this instance, as described, the switch circuit 10C is off, and the first bit line BLn is disconnected from the second bit line FROM_BLn. Therefore, the second bit line FROM_BLn is precharged, but the first bit line BLn is not precharged. Thus, unnecessary precharging of the first bit line BLn is reduced, and the second bit line FROM_BLn alone can be precharged, so that the electric power and time necessary for the precharging of the first bit line BLn can be reduced.

The signal BLX has a voltage (+α) higher than, for example, that of the signal BLC. The signal XXL has a voltage (+β) higher than, for example, that of the signal BLX. Moreover, the signal BLC is set to a voltage about 0.7 V higher than a threshold voltage Vth of the nMOS transistor.

In a discharge period of the sense node SEN from the time t2 to the time t3, the following operation is then performed. At the time t2, the signal HLL shifts to “L” from “H”. Thus, when the voltage of the selected word line WL in the fuse ROM region 10B is higher than the threshold voltage of its memory cells MT, the voltage of the sense node SEN is discharged, and gradually decreases. During the discharge period, a constant voltage of the bit line FROM_BLn is maintained because a charge is supplied through the nMOS transistor 21A or the nMOS transistor 21C.

The following operation is then performed in a sense period from the time t3 to the time t4. At the times t3 to t4, data stored in the memory cells MT in the fuse ROM region 10B is read depending on whether the voltage of the sense node SEN is equal to or more than or is lower than the threshold voltage of the pMOS transistor 21F.

To be specific, the pMOS transistor 21F turns off when the voltage of the sense node SEN is lower than the threshold voltage of the pMOS transistor 21F. As a result, “L” is latched in a node L1 of the sense latch 22, and “H” is latched in a node L2. Thus, data DO(n) output from the sense module 20 becomes “H”.

In contrast, when the voltage of the sense node SEN is equal to or more than the threshold voltage of the pMOS transistor 21F, the pMOS transistor 21F turns on. As a result, “H” is latched in the node L1 of the sense latch 22, and “L” is latched in the node L2. Thus, the data DO(n) output from the sense module 20 becomes “L”.

The power-on read operation for the NAND string 19 connected to the second bit line FROM_BLn+1 is similar to the operation for the NAND string 19 connected to the above-mentioned second bit line FROM_BLn.

### 1.3 Effects of the First Embodiment

According to the present embodiment, the switch circuit 10C is provided to disconnect the first bit line BLn connected to the memory cells in the data region 10A from the second bit line FROM_BLn connected to the memory cells in the fuse ROM region 10B. In the read operation (power-on read operation) for reading various memory parameters during power-on, the switch circuit 10C disconnects the first bit line BLn from the second bit line FROM_BLn connected to the sense circuit. Thus, in the power-on read operation, it is possible to reduce the precharge current for the bit lines, accelerate the read operation, and improve the accuracy of the read operation.

The advantageous effects of the first embodiment are described below in detail.

In the power-on read operation, when the first bit line BLn is disconnected by the switch circuit 10C to precharge the second bit line FROM_BLn, the current necessary to precharge the first bit line BLn can be reduced, and power consumption can therefore be reduced. Moreover, the capacity of the first bit line BLn can be reduced, so that the charging time of the second bit line FROM_BLn can be reduced, and the power-on read operation can be higher. Further, a leak current generated in the first bit line BLn can be reduced, so that the read accuracy can be improved. The advantageous effects can be higher if the fuse ROM region 10B is located closer to the sense circuit. In other words, the advantageous effects can be higher if the distance between the fuse ROM region 10B and the sense circuit is as short as possible.

### 2. Second Embodiment

A semiconductor memory device according to a second embodiment is described. Although the current of the second bit line FROM_BLn is sensed in the first embodiment, the voltage of the second bit line FROM_BLn is sensed in the example shown in the second embodiment.

The overall configuration of the semiconductor memory device according to the second embodiment is similar to that in the first embodiment, and is therefore not described. The configuration of the sense module different from that in the first embodiment is described.

### 2.1 Configuration of Sense Module

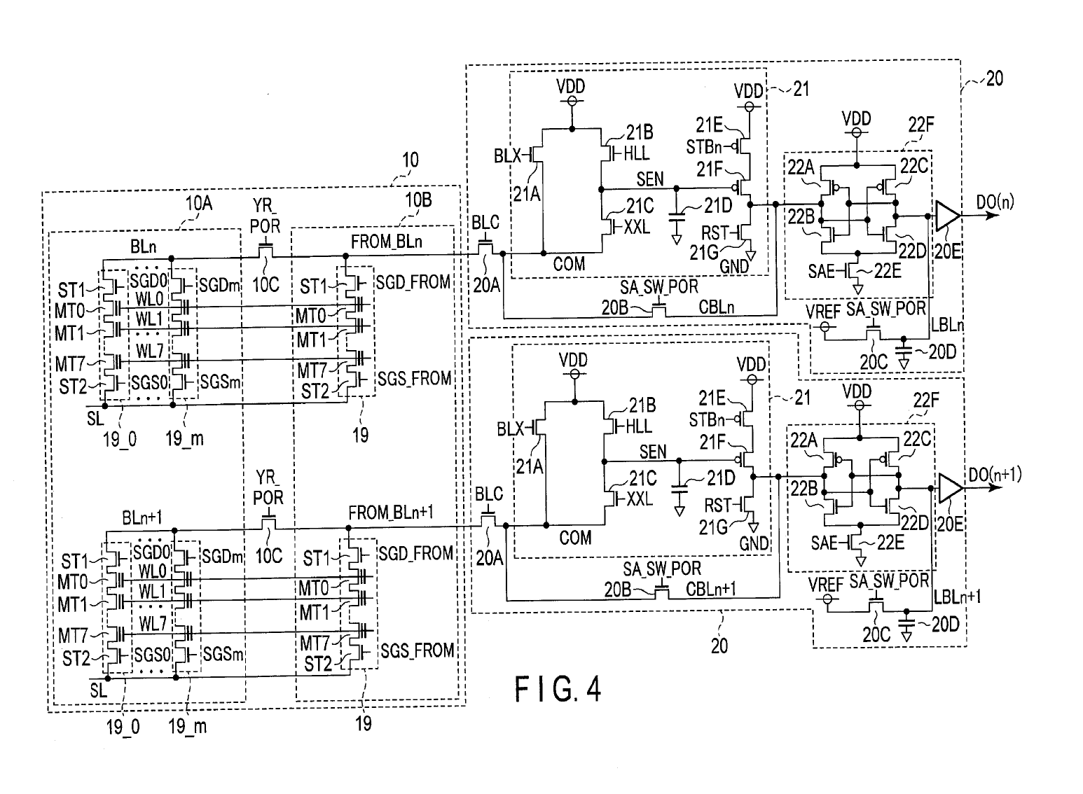

FIG. 4 is a circuit diagram showing the configurations of the memory cell array 10 and the sense modules 20 according to the second embodiment.

The drain of the clamp nMOS transistor 21A is connected to the latch input terminal of a sense latch 22F via a switch circuit 20B. A reference voltage VREF is supplied to the latch output terminal of the sense latch 22F via a switch circuit 20C. Each of the switch circuits 20B and 20C includes an nMOS transistor, and a signal SA_SW_POR is input to its gate. Further, the first electrode of a capacitor 20D is connected to the latch output terminal of the sense latch 22F, and a ground voltage GND is supplied to the second electrode thereof.

A ground voltage is supplied to the sources of the nMOS transistors 22B and 22D of the sense latch 22F via an nMOS transistor 22E. A sense enable signal SAE is input to the gate of an nMOS transistor 22E. A buffer 20E is connected to the latch output terminal of the sense latch 22F.

A connection point between the switch circuit 20B and the latch input terminal of the sense latch 22F is a node CBLn, and a connection point between the switch circuit 20C and the latch output terminal of the sense latch 22F is a node LBLn. The configurations are similar in other respects to those of the memory cell array 10 and the sense modules 20 according to the first embodiment.

As shown in FIG. 4, the NAND strings 19_0 to 19_m and the NAND string 19 are connected to the first bit line BLn+1 and the second bit line FROM_BLn+1 in the memory cell array 10 as well as to the first bit line BLn and the second bit line FROM_BLn, and the sense module 20 is connected to the second bit line FROM_BLn+1.

### 2.2 Operation of Semiconductor Memory Device

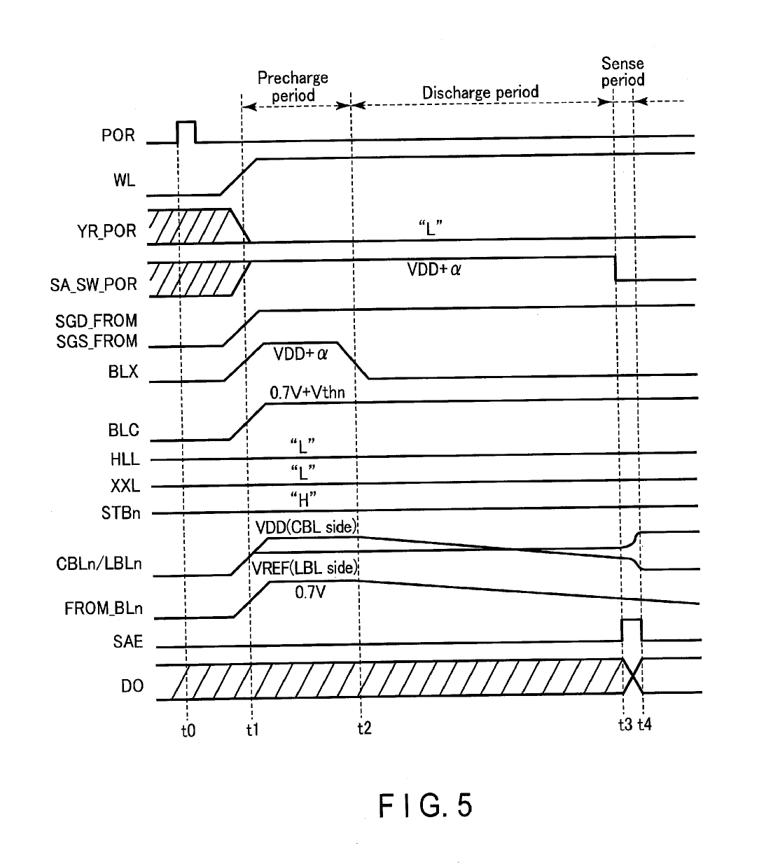

FIG. 5 is a timing chart showing the power-on read operation in the semiconductor memory device according to the second embodiment.

First, at the time to, the power-on reset signal POR is output from the power-on reset circuit in the control circuit 18, and the power-on read operation is then started. At the time t0, the signal YR_POR and the signal SA_SW_POR are “H” or “L”.

Other signals at the time t0 take the following statuses. The word lines WL, the select signals SGD_FROM and SGS_FROM, the signal BLX, the clamp signal BLC, the signal HLL, and the signal XXL are “L”, and the nMOS transistors to which these signals are input are off. The strobe signal STBn is “H”, and the pMOS transistor 21E to which the strobe signal STBn is input is off. The sense enable signal SAE is “L”, and the nMOS transistor 22E is off. Voltages of nodes CBLn and LBLn and the bit line FROM_BLn are “L”.

From the time t1 to the time t4, the power-on read operation is then performed. The following operation is performed in a precharge period from the time t1 to the time t2. At the time t1, the signal YR_POR becomes “L”, and the switch circuit 10C turns off. As a result, the first bit line BLn is disconnected from the second bit line FROM_BLn.

Moreover, at the time t1, the word lines WL, the signal SA_SW_POR, the select signals SGD_FROM and SGS_FROM, the signal BLX, and the signal BLC become “H”, the signal HLL and the signal XXL remain “L”, and the strobe signal STBn remains “H”. As a result, the second bit line FROM_BLn is precharged to 0.7 V. Further, the node CBLn is charged to a power supply voltage VDD, and the node LBLn is charged to the reference voltage VREF. In this instance, as described, the switch circuit 10C is off, and the first bit line BLn is disconnected from the second bit line FROM_BLn. Therefore, the second bit line FROM_BLn is precharged, but the first bit line BLn is not precharged. Thus, unnecessary precharging of the first bit line BLn is reduced, and the second bit line FROM_BLn alone can be precharged, so that the electric power and time necessary for the precharging of the first bit line BLn can be reduced.

The signal SA_SW_POR and the signal BLX have a voltage (+α) higher than, for example, the power supply voltage VDD. Moreover, the signal BLC is set to a voltage about 0.7 V higher than a threshold voltage Vthn of the nMOS transistor.

In the discharge period from the time t2 to the time t3, the following operation is then performed. At the time t2, the signal BLX shifts to “L” from “H”. Thus, when the voltage of the selected word line WL in the fuse ROM region 10B is higher than the threshold voltage of its memory cells MT, the voltages of the second bit line FROM_BLn and the node CBLn are discharged, and gradually decrease. The voltage of the node LBLn is kept at the constant reference voltage VREF.

The following operation is performed in the sense period from the time t3 to the time t4. At the time t3, the signal SA_SW_POR shifts to “L” from “H”. Moreover, at the times t3 to t4, the sense enable signal SAE becomes “H”, and “H” is applied to the gate of the nMOS transistor 22E. As a result, the sense latch 22F is activated, and the sense latch 22F latches the voltage of the node CBLn.

To be specific, when the voltage of the node CBLn is lower than the reference voltage VREF of the node LBLn, the sense latch 22F latches “L” in the node CBLn, and latches “H” in the node LBLn. Thus, the data DO(n) output from the sense module 20 becomes “H”.

In contrast, when the voltage of the node CBLn is higher than the reference voltage VREF of the node LBLn, the sense latch 22F latches “H” in the node CBLn, and latches “L” in the node LBLn. Thus, the data DO(n) output from the sense module 20 becomes “L”.

The power-on read operation for the NAND string 19 connected to the second bit line FROM_BLn+1 is similar to the operation for the NAND string 19 connected to the above-mentioned second bit line FROM_BLn.

### 2.3 Effects of the Second Embodiment

According to the present embodiment, in the read operation (power-on read operation) for reading various memory parameters during power-on, the switch circuit 10C disconnects the first bit line BLn from the second bit line FROM_BLn connected to the sense circuit. Thus, in the power-on read operation, it is possible to reduce the precharge current for the bit lines, accelerate the read operation, and improve the accuracy of the read operation.

Furthermore, in the second embodiment, the voltage sensing is used in the power-on read operation, so that the accuracy of the read operation can be higher than in the first embodiment.

### 3. Third Embodiment

A semiconductor memory device according to a third embodiment is described. In the example shown in the third embodiment, the voltage of the second bit line FROM_BLn and the voltage of the second bit line FROM_BLn+1 are used as complementary data to latch the data stored in the memory cells in the fuse ROM region 10B.

### 3.1 Configuration of Sense Module

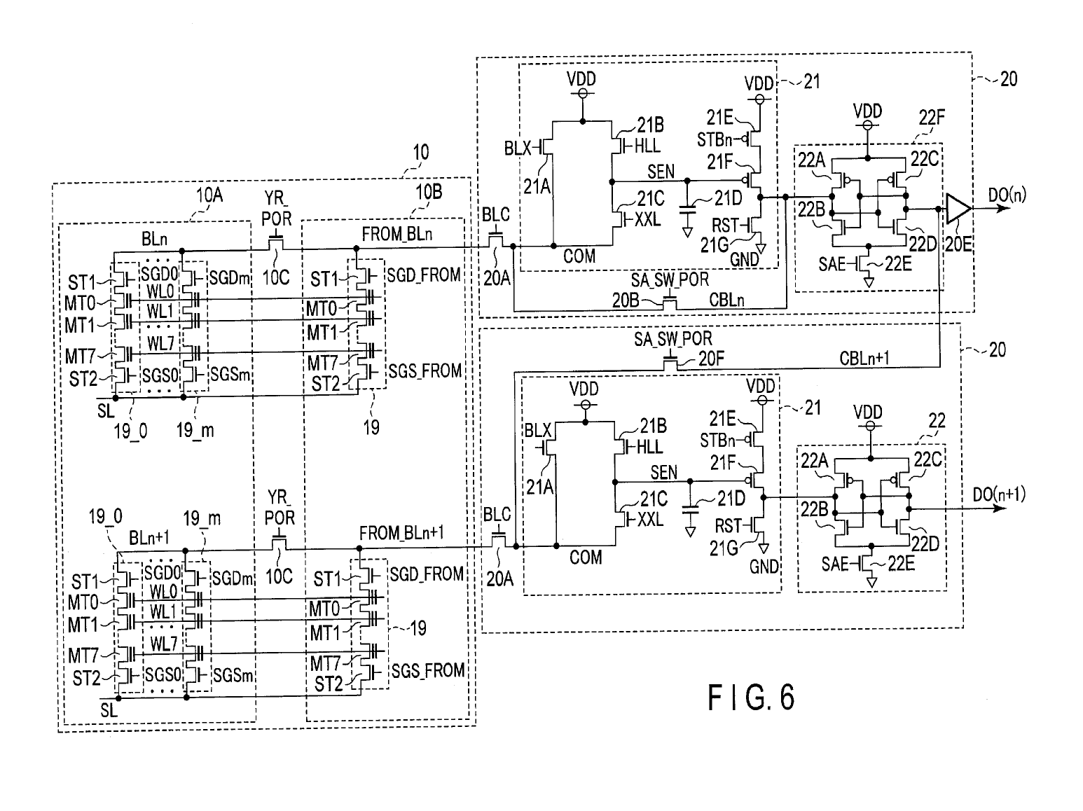

FIG. 6 is a circuit diagram showing the configurations of the memory cell array 10 and the sense modules 20 according to the third embodiment.

The complementary data is stored in the memory cells in the fuse ROM region 10B. Here, the complementary data is stored in the NAND string 19 connected to the second bit line FROM_BLn and in the NAND string 19 connected to the second bit line FROM_BLn+1.

The drain of the clamp nMOS transistor 21A connected to the second bit line FROM_BLn is connected to the latch input terminal of the sense latch 22F via the switch circuit 20B. The drain of the clamp nMOS transistor 21A connected to the second bit line FROM_BLn+1 is connected to the latch output terminal of the sense latch 22F via a switch circuit 20F. Each of the switch circuits 20B and 20F includes an nMOS transistor, and the signal SA_SW_POR is input to its gate.

A ground voltage is supplied to the sources of the nMOS transistors 22B and 22D of the sense latch 22F via the nMOS transistor 22E. The sense enable signal SAE is input to the gate of the nMOS transistor 22E. The buffer 20E is connected to the latch output terminal of the sense latch 22F.

A connection point between the switch circuit 20B and the latch input terminal of the sense latch 22F is a node CBLn, and a connection point between the switch circuit 20F and the latch output terminal of the sense latch 22F is a node CBLn+1. The configurations are similar in other respects to those of the memory cell array 10 and the sense modules 20 according to the first embodiment.

### 3.2 Operation of Semiconductor Memory Device

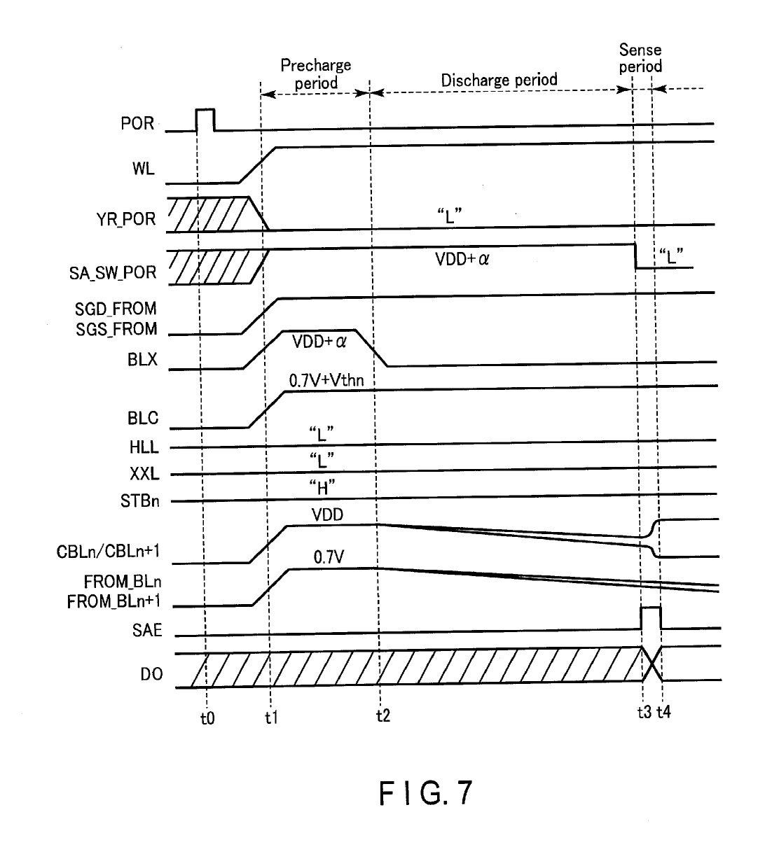

FIG. 7 is a timing chart showing the power-on read operation in the semiconductor memory device according to the third embodiment.

First, at the time to, the power-on reset signal POR is output from the power-on reset circuit in the control circuit 18, and the power-on read operation is then started. At the time to, the signal YR_POR and the signal SA_SW_POR are “H” or “L”.

Other signals at the time t0 take the following statuses. The word lines WL, the select signals SGD_FROM and SGS_FROM, the signal BLX, the clamp signal BLC, the signal HLL, and the signal XXL are “L”, and the nMOS transistors to which these signals are input are off. The strobe signal STBn is “H”, and the pMOS transistor 21E to which the strobe signal STBn is input is off. The sense enable signal SAE is “L”, and the nMOS transistor 22E is off. Voltages of nodes CBLn and CBLn+1 and the bit lines FROM_BLn and FROM_BLn+1 are “L”.

From the time t1 to the time t4, the power-on read operation is then performed. The following operation is performed in a precharge period from the time t1 to the time t2. At the time t1, the signal YR_POR becomes “L”, and the switch circuit 10C turns off. As a result, the second bit line FROM_BLn is disconnected from the first bit line BLn.

Moreover, at the time t1, the word lines WL, the signal SA_SW_POR, the select signals SGD_FROM and SGS_FROM, the signal BLX, and the signal BLC become “H”, the signal HLL and the signal XXL remain “L”, and the strobe signal STBn remains “H”. As a result, the bit lines FROM_BLn and FROM_BLn+1 are precharged to 0.7 V. Further, the nodes CBLn and CBLn+1 are charged to a power supply voltage VDD. In this instance, as described, the switch circuit 10C is off, the first bit line BLn is disconnected from the second bit line FROM_BLn, and the first bit line BLn+1 is disconnected from the second bit line FROM_BLn+1. Therefore, the second bit lines FROM_BLn and FROM_BLn+1 are precharged, but the first bit lines BLn and BLn+1 are not precharged. Thus, unnecessary precharging of the first bit lines BLn and BLn+1 is reduced, and the second bit lines FROM_BLn and FROM_BLn+1 alone can be precharged, so that the electric power and time necessary for the precharging of the first bit lines BLn and BLn+1 can be reduced.

The signal SA_SW_POR and the signal BLX have a voltage (+α) higher than, for example, the power supply voltage VDD. Moreover, the signal BLC is set to a voltage about 0.7 V higher than a threshold voltage Vthn of the nMOS transistor.

In the discharge period from the time t2 to the time t3, the following operation is then performed. At the time t2, the signal BLX shifts to “L” from “H”. Thus, the voltages of the second bit line FROM_BLn and the node CBLn and the voltages of the second bit line FROM_BLn+1 and the node CBLn+1 are discharged, and gradually decrease. Here, the complementary data is stored in the NAND strings 19 respectively connected to the second bit lines FROM_BLn and FROM_BLn+1, so that a potential difference is gradually generated between the second bit line FROM_BLn and the node CBLn and the second bit line FROM_BLn+1 and the node CBLn+1.

The following operation is performed in the sense period from the time t3 to the time t4. At the time t3, the signal SA_SW_POR shifts to “L” from “H”. Moreover, at the times t3 to t4, the sense enable signal SAE becomes “H”, and is applied to the gate of the nMOS transistor 22E. As a result, the sense latch 22F is activated, and the sense latch 22F latches the voltages of the node CBLn and the node CBLn+1.

To be specific, as described above, a potential difference is generated between the node CBLn and the node CBLn+1 due to the difference of cell currents respectively running through the nodes CBLn and CBLn+1. When the voltage of the node CBLn is lower than the voltage of the node CBLn+1, the sense latch 22F latches “L” in the node CBLn, and latches “H” in the node CBLn+1. Thus, the data DO(n) output from the sense module 20 becomes “H”.

In contrast, when the voltage of the node CBLn is higher than the voltage of the node CBLn+1, the sense latch 22F latches “H” in the node CBLn, and latches “L” in the node CBLn+1. Thus, the data DO(n) output from the sense module 20 becomes “L”.

### 3.3 Effects of the Third Embodiment

According to the present embodiment, in the read operation (power-on read operation) for reading various memory parameters during power-on, the switch circuit 10C disconnects the first bit line BLn from the second bit line FROM_BLn connected to the sense circuit, and disconnects the first bit line BLn+1 from the second bit line FROM_BLn+1. Thus, in the power-on read operation, it is possible to reduce the precharge current for the bit lines, accelerate the read operation, and improve the accuracy of the read operation.

Furthermore, in the third embodiment, the complementary data in the memory cells respectively connected to the second bit lines FROM_BLn and FROM_BLn+1 is read by the use of the voltage sensing, so that the accuracy of the read operation can be higher than in the first and second embodiments.

### 4. Peripheral Circuits According to the Embodiments

A selection circuit and an internal power generation circuit used in the above first to third embodiments are described. The selection circuit is provided in the control circuit 18, and the internal power generation circuit is provided in the voltage generation circuit 17.

### 4.1 Configuration of Selection Circuit

The selection circuit generates various control signals for controlling the power-on read operation.

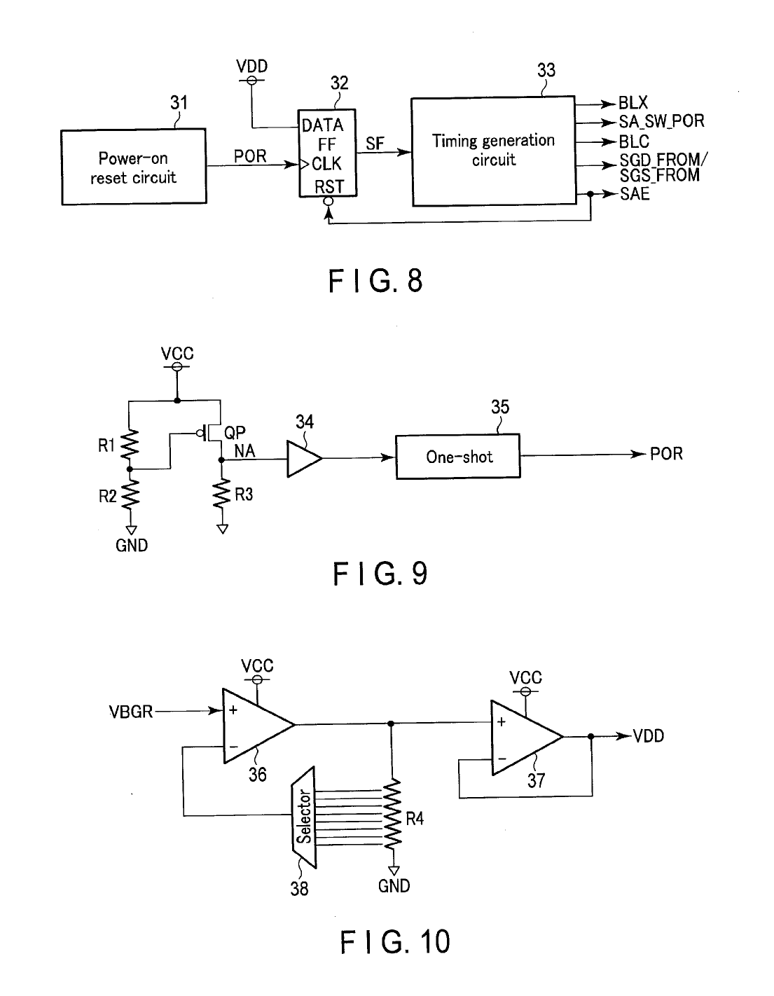

FIG. 8 is a block diagram showing the configuration of the selection circuit according to the embodiments.

As shown, the selection circuit has a power-on reset circuit 31, a flip-flop 32, and a timing generation circuit 33.

The power-on reset circuit 31 detects power-on, that is, an external power supply VCC, and then outputs the power-on reset signal POR to start the power-on read operation. The configuration of the power-on reset circuit 31 will be described later.

The flip-flop 32 outputs a signal SF in accordance with the power-on reset signal POR output from the power-on reset circuit 31.

The timing generation circuit 33 outputs control signals for controlling the power-on read operation such as the signal BLX, the signal SA_SW_POR, the clamp signal BLC, the select signals SGD_FROM and SGS_FROM, and the sense enable signal SAE in accordance with the signal SF output from the flip-flop 32. The sense enable signal SAE is fed back to a reset terminal RST of the flip-flop 32.

FIG. 9 is a circuit diagram showing the configuration of the power-on reset circuit 31.

The power-on reset circuit 31 includes resistors R1, R2, and R3, a pMOS transistor QP, a buffer 34, and a one-shot circuit 35. The external power supply VCC is supplied to one end of the resistor R1 and the source of the pMOS transistor QP. The other end of the resistor R1 is connected to one end of the resistor R2, and a ground voltage GND is supplied to the other end of the resistor R2. The drain of the pMOS transistor QP is connected to one end of the resistor R3, and a ground voltage GND is supplied to the other end of the resistor R3.

Moreover, the drain of the pMOS transistor QP is connected to the one-shot circuit 35 via the buffer 34. The power-on reset signal POR is output from the one-shot circuit 35.

The operation of the power-on reset circuit 31 is as follows: If the external power supply VCC rises and becomes higher than a detection level of the power-on, the pMOS transistor QP turns on. As a result, the potential of a node NA becomes “H”, and “H” is output as the power-on reset signal POR via the buffer 34 and the one-shot circuit 35.

The detection level of the power-on can be represented by “(R1+R2)·|Vthp|/R1”. The ratio of R1/R2 is determined by the detection level of the power-on. Vthp is a threshold voltage of the pMOS transistor QP.

### 4.2 Configuration of Internal Power Generation Circuit

The internal power generation circuit receives the external power supply VCC, and generates the power supply voltage (internal power supply) VDD from the external power supply VCC.

FIG. 10 is a circuit diagram showing the configuration of the internal power generation circuit according to the embodiments.

As shown, the internal power generation circuit includes operational amplifiers 36 and 37, a selector 38, and a resistor R4.

The external power supply VCC is supplied to the operational amplifier 36. A constant voltage VBGR is input to a noninverting input terminal of the operational amplifier 36. A voltage supplied from the selector 38 is input to an inverting input terminal of the operational amplifier 36. The operational amplifier 36 compares the voltages input to the noninverting input terminal and the inverting input terminal, and outputs a voltage corresponding to the comparison result. The voltage VBGR can be generated by the use of, for example, a band gap reference circuit.

The voltage output from the operational amplifier 36 is supplied to one end of the resistor R4. A ground voltage GND is supplied to the other end of the resistor R4. The resistor R4 has nodes different in resistance value. The selector 38 selects one of the nodes of the resistor R4, and supplies the voltage of this node to the inverting input terminal of the operational amplifier 36.

Furthermore, the voltage output from the operational amplifier 36 is supplied to the noninverting input terminal of the operational amplifier 37. The external power supply VCC is supplied to the operational amplifier 37. The power supply voltage (internal power supply) VDD is output from the operational amplifier 37, and this power supply voltage VDD is fed back to an inverting input terminal of the operational amplifier 37.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first select transistor electrically connected to a first memory cell;
a first bit line electrically connected to the first select transistor;
a second select transistor electrically connected to a second memory cell;
a second bit line electrically connected to the second select transistor;
a first switch circuit electrically connected between the first bit line and the second bit line; and
a sense amplifier which is electrically connected to the second bit line and which senses data stored in the first memory cell and the second memory cell.

2. The semiconductor memory device according to claim 1, wherein
during power-on, the first switch circuit disconnects the first bit line from the second bit line, and the sense amplifier precharges the second bit line.

3. The semiconductor memory device according to claim 1, wherein
the second memory cell stores various memory parameters to be set during power-on.

4. The semiconductor memory device according to claim 1, wherein
the first switch circuit includes a transistor.

5. The semiconductor memory device according to claim 1, wherein
during a read operation, the first switch circuit connects the first bit line to the second bit line, and the sense amplifier precharges the first bit line and the second bit line.

6. The semiconductor memory device according to claim 1, further comprising
first and second NAND strings including memory cell transistors connected in series by the sources or drains thereof,
wherein the first memory cell is a memory cell transistor included in the first NAND string, and the second memory cell is a memory cell transistor included in the second NAND string.

7. The semiconductor memory device according to claim 6, wherein
the gates of the memory cell transistors in the first NAND string and the gates of the memory cell transistors in the second NAND string are electrically connected by a word line, respectively.

8. The semiconductor memory device according to claim 1, further comprising:
a latch circuit including a first terminal and a second terminal to latch data;
a power supply terminal which supplies a reference voltage;
a second switch circuit electrically connected between the second bit line and the first terminal; and
a third switch circuit electrically connected between the power supply terminal and the second terminal.

9. The semiconductor memory device according to claim 8, wherein
the first, second, and third switch circuits include transistors.

10. A semiconductor memory device comprising:
a first select transistor electrically connected to a first memory cell;
a first bit line electrically connected to the first select transistor;
a second select transistor electrically connected to a second memory cell;
a second bit line electrically connected to the second select transistor;
a first switch circuit electrically connected between the first bit line and the second bit line;
a first sense amplifier which is electrically connected to the second bit line and which senses data stored in the first memory cell and the second memory cell;
a first latch circuit including a first terminal and a second terminal to latch the data sensed by the first sense amplifier;
a second switch circuit electrically connected between the second bit line and the first terminal;
a third select transistor electrically connected to a third memory cell;
a third bit line electrically connected to the third select transistor;
a fourth select transistor electrically connected to a fourth memory cell;
a fourth bit line electrically connected to the fourth select transistor;
a third switch circuit electrically connected between the third bit line and the fourth bit line;
a second sense amplifier which is electrically connected to the fourth bit line and which senses data stored in the third memory cell and the fourth memory cell;
a second latch circuit which latches the data sensed by the second sense amplifier; and
a fourth switch circuit electrically connected between the fourth bit line and the second terminal.

11. The semiconductor memory device according to claim 10, wherein
during power-on, the first switch circuit disconnects the first bit line from the second bit line, the second switch circuit connects the second bit line to the first terminal, and the first sense amplifier precharges the second bit line, and
the third switch circuit disconnects the third bit line from the fourth bit line, the fourth switch circuit connects the fourth bit line to the second terminal, and the second sense amplifier precharges the fourth bit line.

12. The semiconductor memory device according to claim 10, wherein
the second and fourth memory cells store various memory parameters to be set during power-on.

13. The semiconductor memory device according to claim 10, wherein
the first, second, third, and fourth switch circuits include transistors.

14. The semiconductor memory device according to claim 10, wherein
during a read operation, the first switch circuit connects the first bit line to the second bit line, and the first sense amplifier precharges the first bit line and the second bit line, and
the third switch circuit connects the third bit line to the fourth bit line, and the second sense amplifier precharges the third bit line and the fourth bit line.

15. The semiconductor memory device according to claim 10, further comprising
first, second, third, and fourth NAND strings including memory cell transistors electrically connected in series by the sources or drains thereof,
wherein the first, second, third, and fourth memory cells are the memory cell transistors included in the first, second, third, and fourth NAND strings, respectively.
